(19) United States
(12) Patent Application Publication
(10) Pub. No.: US 2001/0006839 A1
(43) Pub. Date: Jul. 5, 2001

(54) Method for manufacturing shallow trench isolation in semiconductor device

(76) Inventor: In-Seok Yeo, Ichon-shi (KR)

Correspondence Address: JACOBSON, PRICE, HOLMAN & STERN, PROFESSIONAL LIMITED LIABILITY COMPANY, 400 Seventh Street, N.W., Washington, DC, 20004, US

(21) Appl. No.: 09/737,560

(22) Filed: Dec. 18, 2000

(30) Foreign Application Priority Data
Dec. 30, 1999 (KR) 1999-65832

(51) Int. Cl. H01L 21/76

(52) U.S. Cl. 438/435; 438/424

(57) ABSTRACT

A method for manufacturing a shallow trench isolation in a semiconductor device, the method including the steps of forming a trench mask patterned layer on a semiconductor substrate, forming a narrow trench and a wide trench by etching an exposed substrate, forming a second insulating layer on the entire surface including the trenches and the trench mask patterned layer whereby the narrow trench is completely filled and the wide trench is partially filled, and forming a third insulating layer on the first insulating layer, whereby the wide trench is filled completely.

### FIELD OF THE INVENTION

The present invention relates to a method for manufacture of a semiconductor memory device; and, more particularly, to a method for manufacturing a shallow trench isolation in the semiconductor device with good gap-fill capability.

### DESCRIPTION OF THE PRIOR ART

In a semiconductor device, a great number of devices and circuits are fabricated on a single semiconductor substrate. Various kinds of devices like transistors, resistors, and capacitors are formed together. These devices must operate independently without interfering with each other, especially under the higher and higher packing density of the integrated circuits. An isolation region is formed on the semiconductor substrate for separating different devices or different functional regions. The isolation region has an important role in preventing current leakage between two adjacent active regions.

Local oxidation of silicon (LOCOS) is a widely applied technology in forming the isolation region because LOCOS technology provides the isolation region with a simple manufacturing process and low cost. However, as the semiconductor integrated circuits become more densely packed, the application of the LOCOS technology is quite limited. For highly integrated circuits with devices of deep sub-micrometer sizes, the LOCOS process has a problem of filling insulating material thereinto. Furthermore, the LOCOS isolation process suffers bird's beak due to lateral oxidation during thermal oxidation processes. This results in gate oxide deterioration and active regions eventually become narrow.

The shallow trench isolation (STI) process is another isolation process proposed especially for semiconductor device swith high integration like 256 Megabit DRAM and beyond. Thus, the STI process is popularly being used for highly packed semiconductor devices, because it provides a solution to prevent the deterioration of isolation properties due to bird's beak when design rule is reduced.

According to a conventional STI process, representatively shown in FIG. 1, a trench region is formed in the silicon substrate 110 with a depth deep enough for isolating the different devices or wells. Generally, a trench is etched by using a pad oxide 112 and nitride layer 114 as a mask and refilled with insulating materials 116 in the trench isolation process. The refilled trench regions are made to be flat by using a method such as a chemical mechanical polishing (CMP). Finally, the shallow trench isolation is formed after removing the pad oxide 112 and nitride layer 114.

In the conventional STI process, a CVD oxide is mainly used as the insulating material to be refilled into the trench region. But this has a limitation when providing an enhanced gap-fill capability for a narrow trench region 118. In recent times, a high density plasma chemical vapor deposition (HDP-CVD) or O₃-tetra-ethyl-ortho-silicate (TEOS) oxide is used to solve the gap-fill problem. But, even though O₃-TEOS or HDP-CVD oxide is used as the insulating material is used to improve the gap-fill capability, it is reported that voids “A” may be produced, as shown in FIG. 1, in Gigabit DRAM provided with the trench isolation having the depth of approximately 0.25 μm and the width of approximately 0.1 μm.

### SUMMARY OF THE INVENTION

It is, therefore, an object of the present invention to provide a method for manufacturing a shallow trench isolation (STI) in a semiconductor device with enhanced gap-fill capability, thereby preventing the formation of voids in an insulating material to be filled in the STI.

In accordance with one aspect of the present invention, there is provided a method for manufacturing a shallow trench isolation in a semiconductor device, the method comprising the steps of: a) forming a trench mask patterned layer on a semiconductor substrate; b) forming a narrow trench and a wide trench by etching an exposed substrate; c) forming a second insulating layer on the entire surface including the trenches and the trench mask patterned layer whereby the narrow trench is completely filled and the wide trench is partially filled; and d) forming a third insulating layer on the first insulating layer, whereby the wide trench is filled completely.

### BRIEF DESCRIPTION OF THE DRAWINGS

The above and other objects and features of the present invention will become apparent from the following description of the preferred embodiments given in conjunction with the accompanying drawings, in which:

FIG. 1 shows a cross sectional view of a shallow trench isolation (STI) in accordance with a conventional STI method; and

FIGS. 2A to 2G are schematic cross sectional views setting forth a method for forming STI in accordance with a preferred embodiment of the present invention.

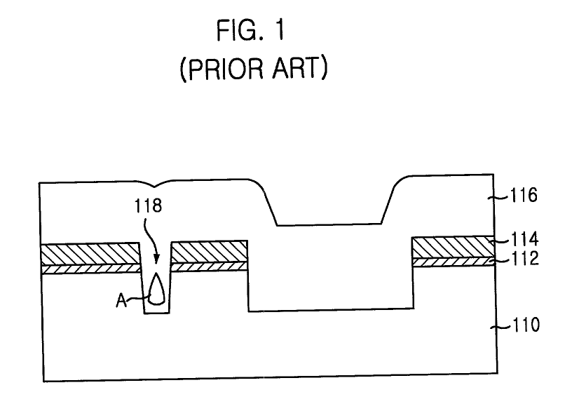

### DETAILED DESCRIPTION OF THE PREFERRED EMBODIMENTS

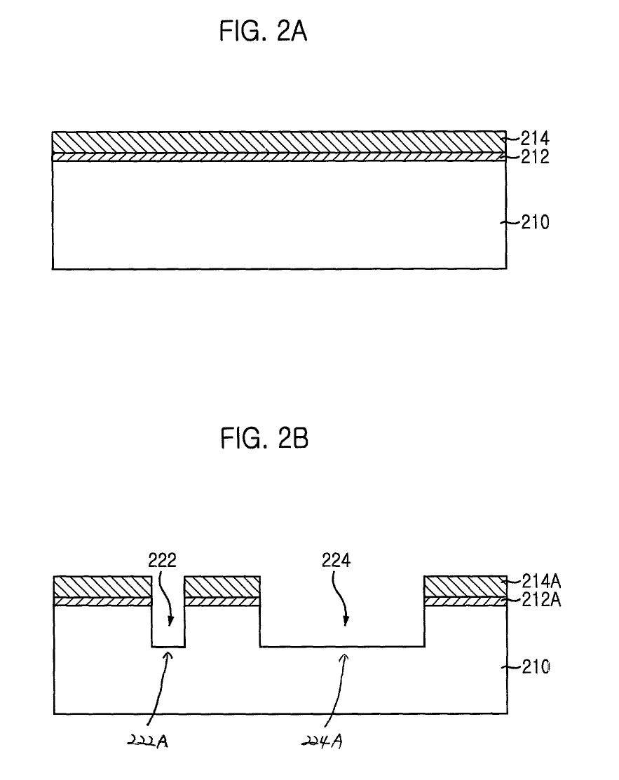

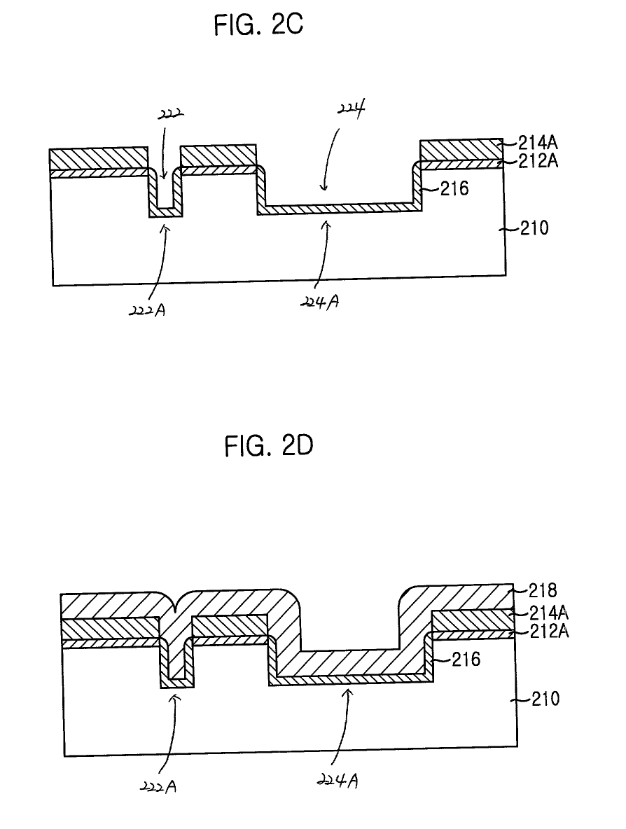

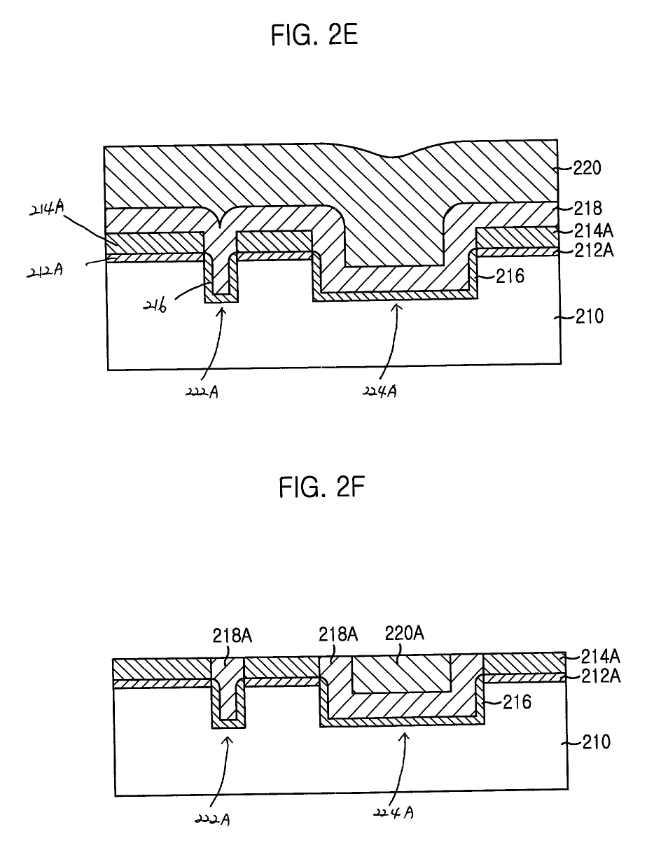

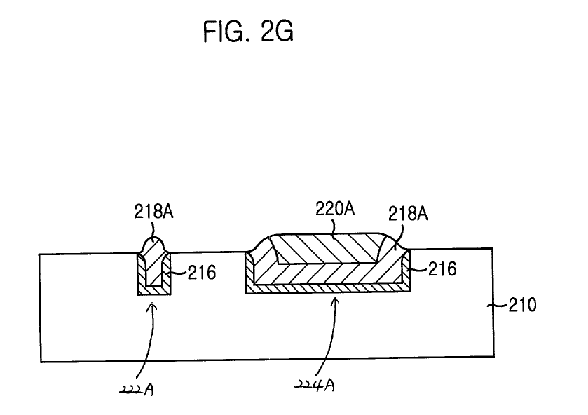

There are provided in FIGS. 2A to 2G cross sectional views setting forth a method for the manufacture of a shallow trench isolation in accordance with a preferred embodiment of the present invention. It should be noted that like parts appearing in FIGS. 2A to 2G are represented by like reference numerals.

As shown in FIG. 2A, an oxide layer 212 and a nitride layer 214 are formed on top of a silicon substrate 210 to a thickness ranging from 25˜200 Å and 1,000˜2,000 Å, respectively. The oxide layer 212 serves as a buffer layer for relieving an induced stress of the nitride layer 214 due to thermal expansion characteristics. The combination of the oxide and the nitride layers 212, 214 serves as a masking layer for defining the active regions.

In a next step as shown in FIG. 2B, the oxide and the nitride layers 212, 214 are patterned and etched into a predetermined configuration using a method of a photolithography and a dry-etching process like a reactive ion etching (RIE), whereby a patterned oxide layer 212A and a patterned nitride layer 214A are obtained. And then, an exposed portion of the substrate 210 is etched to a depth of 2,000˜4,000 Å to obtain two openings 222, 224 of approximate trench regions 222A, 224A, wherein one narrow opening 222 is formed around the memory cells and the other wide opening 224 is formed around a peripheral circuit region.

In an ensuing step as shown in FIG. 2C, wet oxidation and wet etching processes (not shown) are carried out for recovering etching damage on the surface of the substrate 210 during the previous etching, which may have been RIE. After this, a first insulating layer 216, i.e., oxide layer, is formed on the openings 222, 224 to the thickness of 100˜200 Å by a high temperature oxidation process. The high temperature oxidation process is carried out at approximately 800˜1,000° C. by using a dry or a wet oxidation process. The first insulating layer 216 plays a role in improving an isolation property and gap-fill capability. Furthermore, another nitride layer (not shown) may be formed additionally on the first insulating layer 216 for preventing a thermal oxidation in the trench during subsequent oxidation processes.

Thereafter, as shown in FIG. 2D, a second insulating layer 218, e.g., silicon oxide layer, is formed on the entire surface including the first insulating layer 216 and the patterned nitride layer 214A by using a method such as an atomic layer deposition (ALD), wherein the deposition temperature is preferably 300˜500° C. The second insulating layer 218 is grown up to a thickness more than half of a minimum design rule, e.g., preferably 300˜500 Å so that the narrow opening 222 of the trench region 222A formed around the memory cell is completely filled therewith. The growth of the second insulating layer 218 is performed by implanting a silicon source such as SiCl₄, SiH₂Cl₂ or the like, and an oxygen source such as H₂O, alcohol or the like, in turn.

In a next step as shown in FIG. 2E, a third insulating layer 220, e.g., silicon oxide layer, is formed on top of the second insulating layer 218 by using a method such as a high density plasma chemical vapor deposition (HDP-CVD), O₃-tetra-ethyl-ortho-silicate (TEOS) or a low-pressure chemical vapor deposition (LPCVD). At this time, the thickness of the third insulating layer 220 should be greater than approximately 5,000 Å which is greater than the depths of the trench regions 222A, 224A.

In an ensuing step as shown in FIG. 2F, a chemical mechanical polishing (CMP) is carried out to flatten an upper surface of the device by making use of the patterned nitride layer 214A as a polishing stop. After the CMP process, a thermal treatment is carried out at approximately 900˜1,100° C. for 20˜40 minutes to increase the density of the second and the third insulating layers 218A, 220A. The thermal treatment may be carried out after deposition of the third insulating layer 220 and before the CMP process.

Finally, as shown in FIG. 2G, the patterned oxide layer 212A and the patterned nitride layer 214A are removed by a wet etching process for forming active devices like transistors (not shown).

In the STI process of the present invention, the narrow trench region 222A is filled with the insulating material, e.g., SiO₂, by using an ALD method which is known to have 100% step coverage, so that there are no gaps and voids therein. That is, since the ALD method utilizes a surface reaction which is able to form the material on the surface only using an adsorption and desorption phenomena, it is possible to obtain 100% step coverage. On the other hand, the conventional CVD method utilizes a gas phase reaction so that the step coverage is relatively lower than that of the ALD method.

However, the film growth rate when using the ALD method is usually 10˜100 Å per minute, so that productivity is decreased. Therefore, in the present invention, anALD method is only used to fill the narrow trench region 222A around the memory cells completely with the insulating material. In the wide trench region 224A around the peripheral circuit region, the conventional HDP-CVD or O₃-TEOS is used to complete filling of the wide trench region 224A with the insulating material because this conventional method has a productivity advantage for wide region deposition.

Although the preferred embodiments of the invention have been disclosed for illustrative purposes, those skilled in the art will appreciate that various modifications, additions and substitutions are possible, without departing from the scope and spirit of the invention as disclosed in the accompanying claim.

What is claimed is:

1. A method for manufacturing a shallow trench isolation in a semiconductor device, the method comprising the steps of:
a) forming a trench mask patterned layer on a semiconductor substrate;
b) forming a narrow trench and a wide trench by etching an exposed substrate;
c) forming a second insulating layer on a surface including the trenches and the trench mask patterned layer whereby the narrow trench is filled and the wide trench is partially filled; and
d) forming a third insulating layer on the first insulating layer, whereby the wide trench is filled.

2. The method as recited in claim 1, wherein the step c) is carried out by using an atomic layer deposition (ALD) method.

3. The method as recited in claim 2, wherein the second insulating layer is formed to a thickness of more than half of a minimum design rule, ranging from 300 Å to 500 Å.

4. The method as recited in claim 1, further comprising between the steps b) and c), a step of forming a first insulating layer on surfaces of the narrow and the wide trenches.

5. The method as recited in claim 4, wherein a thickness of the first insulating layer is approximately 100 Å to 200 Å.

6. The method as recited in claim 1, after the step d), further comprising the steps of:
e) polishing the second and the third insulating layers by using a chemical mechanical polishing method;
f) carrying out a thermal treatment to densify the second and the third insulating layers; and
g) removing the trench mask patterned layer for forming active devices.

7. The method as recited in claim 4, further comprising the step of forming a nitride layer on the first insulating layer.

8. The method as recited in claim 1, wherein the step d) is carried out by using a method selected from the group consisting of a high density plasma chemical vapor deposition (HDP-CVD) , O₃-tetra-ethyl-ortho-silicate (TEOS) or a low-pressure chemical vapor deposition (LPCVD).

9. The method as recited in claim 6, wherein the step f) is carried out at approximately 900˜1,000° C. for 20˜40 minutes in a dry oxygen containing ambient.

10. The method as recited in claim 7, wherein a thickness of the third insulating layer is greater than depths of the trenches.
